(19) United States
(12) Patent Application Publication
(10) Pub. No.: US 2024/0184193 A1
(43) Pub. Date: Jun. 6, 2024

(54) MASK BLANK, REFLECTIVE MASK, AND METHOD FOR PRODUCING SEMICONDUCTOR DEVICE

(71) Applicant: HOYA CORPORATION, Tokyo (JP)

(72) Inventors: Yohei IKEBE, Tokyo (JP); Takashi UCHIDA, Tokyo (JP)

(73) Assignee: HOYA CORPORATION, Tokyo (JP)

(21) Appl. No.: 18/556,839

(22) PCT Filed: May 6, 2022
(86) PCT No.: PCT/JP2022/019567

§ 371 Date: Oct. 23, 2023

(30) Foreign Application Priority Data
May 27, 2021 (JP) 2021-089300

(51) Int. Cl. G03F 1/24; G03F 1/48

(52) U.S. Cl. CPC G03F 1/24; G03F 1/48

(57) ABSTRACT

[Problem] Provided is a mask blank

[Solution] A mask blank comprises a multilayer reflective film and a pattern forming thin film in this order on a main surface of a substrate. The thin film is made of a material containing a metal, and when a refractive index of the thin film with respect to light having a wavelength λ_{L} of 13.2 nm is represented by n_{L}, a refractive index of the thin film with respect to light having a wavelength λ_{M} of 13.5 nm is represented by n_{M}, a refractive index of the thin film with respect to light having a wavelength λ_{H} of 13.8 nm is represented by n_{H}, and a coefficient P=[(1−n_{H})/λ_{H}−(1−n_{L})/λ_{L})]/[(1−n_{M})/λ_{M}] is satisfied, an absolute value of the coefficient P is 0.09 or less.

### CROSS-REFERENCE TO RELATED APPLICATIONS

This application is the National Stage of International Application No. PCT/JP2022/019567, filed May 6, 2022, which claims priority to Japanese Application No. 2021-089300, filed May 27, 2021, and the contents of which is incorporated by reference.

### TECHNICAL FIELD

The present disclosure relates to a mask blank that is an original plate for manufacturing an exposure mask used, for example, for manufacturing a semiconductor device, a reflective mask, and a method for manufacturing a semiconductor device.

### BACKGROUND ART

An exposure apparatus in manufacture of a semiconductor device has evolved while gradually shortening a wavelength of a light source. In order to achieve finer pattern transfer, extreme ultraviolet (EUV) light (hereinafter, also referred to as EUV light) lithography using EUV light having a wavelength around 13.5 nm has been developed. In the EUV lithography, a reflective mask is used because there are few materials transparent to EUV light. Typical examples of the reflective mask include a reflective binary mask and a reflective phase shift mask (reflective halftone phase shift mask).

Patent Documents 1 and 2 describe techniques related to such an EUV lithography reflective mask and a mask blank for manufacturing the same.

Patent Document 1 discloses an extreme ultraviolet exposure mask including a high reflection portion formed of a multilayer film formed on a substrate and a low reflection portion formed of a single layer film formed on a part of the multilayer film. In this mask, reflected light from the low reflection portion has a reflectance of 5 to 15% with respect to reflected light from the high reflection portion, and has a phase difference of 175 to 185 degrees with respect to reflected light from the high reflection portion, and a refractive index (1−δ) and an extinction coefficient β for an exposure wavelength of a single layer film constituting the low reflection portion are in a region connecting predetermined point coordinates (1−δ, β) in plane coordinates having the refractive index (1−δ) and the extinction coefficient β as coordinate axes.

Patent Document 2 discloses a reflective mask blank including, on a substrate, a multilayer reflective film, a protective film, and a phase shift film that shifts a phase of EUV light in this order. In this reflective mask blank, a surface of the phase shift film has a reflectance of more than 3% and 20% or less, the phase shift film is constituted by a material made of an alloy containing two or more types of metals so as to have a predetermined phase difference of 170 degrees to 190 degrees, the alloy selects one or more types of metal elements from each of group A and group B, in which the group A is a group of metal elements satisfying a refractive index n and an extinction coefficient k of k>α*n+β, and the group B is a group of metal elements satisfying a refractive index n and an extinction coefficient k of k<α*n+β, and a composition ratio is adjusted such that a change amount of the phase difference is in a range of ±2 degrees and a change amount of the reflectance is in a range of ±0.2% when a film thickness of the phase shift film changes by ±0.5% with respect to a set film thickness. (Note that a represents a proportional constant, and B represents a constant.)

### PRIOR ART DOCUMENTS

### Patent Documents

Patent Document 1: JP 2006-228766 A
Patent Document 2: JP 2018-146945 A

### SUMMARY OF DISCLOSURE

### Technical Problem

The finer a pattern is and the more accurate a pattern dimension or a pattern position is, the more electrical characteristics and performance of a semiconductor device are improved, the more a degree of integration can be improved, and the more a chip size can be reduced. Therefore, EUV lithography is required to have pattern transfer performance with a higher level of accuracy and a finer dimension than before. At present, ultrafine and highly accurate pattern formation corresponding to an hp 16 nm (half pitch 16 nm) generation is required. In response to such a demand, a reflective mask using EUV light as exposure light and further using a phase shift effect is required.

In a reflective mask using such a phase shift effect, a multilayer reflective film is disposed on a main surface of a substrate at a center wavelength of EUV light of 13.5 nm, and a pattern forming thin film (for example, an absorber film) disposed on the multilayer reflective film is designed so as to have a phase shift effect.

In the reflective mask, further improvement of exposure transfer characteristics is required. In particular, in a case of a reflective mask including a thin film (for example, an absorber pattern) on which a transfer pattern using a phase shift effect is formed, further improvement of optical characteristics of this thin film is required.

Therefore, an aspect of the present disclosure is to provide a mask blank capable of manufacturing a reflective mask capable of exhibiting excellent transfer characteristics when exposure transfer is performed with an EUV exposure apparatus.

Another aspect of the present disclosure is to provide a reflective mask capable of exhibiting excellent transfer characteristics when exposure transfer is performed with an EUV exposure apparatus, and to provide a method for manufacturing a semiconductor device using the reflective mask.

### Solution to Problem

In order to solve the above problems, the present disclosure has the following configurations.

(Configuration 1)

A mask blank comprising a multilayer reflective film and a pattern forming thin film in this order on a main surface of a substrate, in which
the thin film is made of a material containing a metal, and
when a refractive index of the thin film with respect to light having a wavelength λ_{L} of 13.2 nm is represented by n_{L},
a refractive index of the thin film with respect to light having a wavelength λ_{M} of 13.5 nm is represented by n_{M},
a refractive index of the thin film with respect to light having a wavelength λ_{H} of 13.8 nm is represented by n_{H}, and
a coefficient P=[(1−n_{H})/λ_{H}−(1−n_{L})/λ_{L})]/[(1−n_{M})/λ_{M}] is satisfied, an absolute value of the coefficient P is 0.09 or less.

(Configuration 2)

The mask blank according to configuration 1, in which the refractive index n_{M} of the thin film with respect to light having the wavelength λ_{M} is 0.96 or less.

(Configuration 3)

The mask blank according to configuration 1 or 2, in which the thin film has a thickness of less than 100 nm.

(Configuration 4)

The mask blank according to any one of configurations 1 to 3, comprising a protective film between the multilayer reflective film and the thin film.

(Configuration 5)

The mask blank according to any one of configurations 1 to 4, in which the thin film causes a phase difference of 130 degrees to 230 degrees between reflected light from the thin film and reflected light from the multilayer reflective film with respect to light having the wavelength λ_{M}.

(Configuration 6)

A reflective mask comprising a multilayer reflective film and a thin film having a transfer pattern formed thereon in this order on a main surface of a substrate, in which
the thin film is made of a material containing a metal, and
when a refractive index of the thin film with respect to light having a wavelength λ_{L} of 13.2 nm is represented by n_{L},
a refractive index of the thin film with respect to light having a wavelength λ_{M} of 13.5 nm is represented by n_{M},
a refractive index of the thin film with respect to light having a wavelength λ_{H} of 13.8 nm is represented by n_{H}, and
a coefficient P=[(1−n_{H})/λ_{H}−(1−n_{L})/λ_{L})]/[(1−n_{M})/λ_{M}] is satisfied,
an absolute value of the coefficient P is 0.09 or less.

(Configuration 7)

The reflective mask according to configuration 6, in which the refractive index n_{M} of the thin film with respect to light having the wavelength λ_{M} is 0.96 or less.

(Configuration 8)

The reflective mask according to configuration 6 or 7, in which the thin film has a thickness of less than 100 nm.

(Configuration 9)

The reflective mask according to any one of configurations 6 to 8, comprising a protective film between the multilayer reflective film and the thin film.

(Configuration 10)

The reflective mask according to any one of configurations 6 to 9, in which the thin film causes a phase difference of 130 degrees to 230 degrees between reflected light from the thin film and reflected light from the multilayer reflective film with respect to light having the wavelength λ_{M}.

(Configuration 11)

A method for manufacturing a semiconductor device, the method comprising performing exposure transfer of the transfer pattern to a resist film on a semiconductor substrate using the reflective mask according to any one of configurations 6 to 10.

### Advantageous Effects of Disclosure

According to the present disclosure, it is possible to provide a mask blank capable of manufacturing a reflective mask capable of exhibiting excellent transfer characteristics when exposure transfer is performed with an EUV exposure apparatus.

In addition, according to the present disclosure, it is possible to provide a reflective mask capable of manufacturing a reflective mask capable of exhibiting excellent transfer characteristics when exposure transfer is performed with an EUV exposure apparatus, a method for manufacturing the reflective mask, and a method for manufacturing a semiconductor device using the reflective mask.

### BRIEF DESCRIPTION OF DRAWINGS

FIG. 1 is a schematic cross-sectional view of a main part for describing an example of a schematic configuration of a reflective mask blank of an embodiment of the present disclosure.

FIG. 2 is a schematic cross-sectional view of a main part for describing an example of a schematic configuration of the reflective mask blank to a reflective mask.

FIG. 3 is a graph illustrating a relationship between a reflectance on a multilayer reflective film and a wavelength when EUV light is used as exposure light in the reflective mask blank of the embodiment of the present disclosure.

### DESCRIPTION OF EMBODIMENTS

Hereinafter, an embodiment of the present disclosure will be described, and first, circumstances leading to the present disclosure will be described. The present inventors have intensively conducted studies on a means capable of exhibiting excellent transfer characteristics when exposure transfer is performed with an EUV exposure apparatus.

The present inventors have considered that optical characteristics of an absorber pattern of a reflective mask can be improved by considering a wavelength band other than a center wavelength of EUV light in selecting a material of an absorber film constituting a pattern forming thin film. This will be described with reference to FIG. 3. FIG. 3 is a graph illustrating a relationship between a reflectance on a multilayer reflective film and a wavelength when EUV light is used as exposure light in a reflective mask blank of the embodiment of the present disclosure. As can be understood from the drawing, EUV light incident on a multilayer reflective film in an EUV exposure apparatus has a certain degree of amplitude not only at a center wavelength of 13.5 nm but also in a wavelength band in the vicinity thereof. As illustrated in the drawing, the multilayer reflective film has a high reflectance exceeding 70% at a center wavelength of 13.5 nm, but has a non-negligible reflectance even in a wavelength band in the vicinity thereof. For example, the multilayer reflective film has a reflectance exceeding 10% in a wavelength band of 13.0 nm to 14.0 nm, and has a reflectance exceeding 30% in a wavelength band of 13.2 nm to 13.8 nm.

A refractive index n of a film material changes depending on a wavelength of exposure light. Meanwhile, in a reflective mask, a phase difference φ between EUV light reflected by a multilayer reflective film and EUV light reflected by an absorber film can be calculated by the following relational formula (1) using a wavelength z of light, a refractive index n at the wavelength 2, and a film thickness d (an optical path difference is 2d because of a reflective type).

Phase difference φ between EUV light reflected by a multilayer reflective film and EUV light reflected by an absorber film:

2π(1−n)×2d/λ=4π(1−n)d/λ (1)

As the phase difference φ is closer to the same numerical value at each wavelength of EUV light having a wavelength band (as a variation Δφ of the phase difference φ at each wavelength of EUV light having a wavelength band is smaller), it is estimated that a phase shift effect is improved.

In the above formula (1), the film thickness d is restricted from a viewpoint of optical characteristics. Therefore, attention is paid to the portion of 4π(1−n)/λ excluding the film thickness d in the above formula (1).

As a result of intensive studies, it has been concluded that when refractive indices of a thin film with respect to light beams having wavelengths λ_{L}=13.2 nm, λ_{M}=13.5 nm, and λ_{H}=13.8 nm are represented by n_{L}, n_{M}, and n_{H}, respectively, and a coefficient λ_{L}=4π×(1−n_{L})/λ_{L}, a coefficient A_{M}=4π×(1−n_{M})/λ_{M}, a coefficient A_{H}=4π×(1−n_{H})/λ_{H}, and a coefficient P=(A_{H}−A_{L})/A_{M} are satisfied, in a case where the thin film satisfies a condition of |P|<0.09, a magnitude of a variation Δφ (=φ_{H}−φ_{L}, hereinafter, also simply referred to as “phase difference Δφ”) that is a phase difference between φ_{L} and φ_{H} in the wavelength band of λ_{L}=13.2 nm to λ_{H}=13.8 nm of EUV light can be suppressed to 20 degrees or less when exposure transfer is performed with an EUV exposure apparatus, and excellent transfer characteristics can be exhibited. Here, the coefficient P can be expanded as follows.

Coefficient P=(A_{H}−A_{L})/λ_{M}=[(1−n_{H})/λ_{H}−(1−n_{L})/λ_{L})]/[(1−n_{M})/λ_{M}]

The present disclosure has been made as a result of intensive studies as described above. Note that the above-described method for deriving the coefficient P does not limit the scope of rights of the present disclosure (Coefficients A_{L}, A_{M}, and A_{H} are not essential elements of the present disclosure.).

In the present embodiment, design is made such that a phase difference φ_{M} at a center wavelength λ_{M} of EUV light is about 1.2 n (about 216 degrees). This is because an effective reflection surface is located closer to a substrate than an interface between an absorber film and a multilayer reflective film due to occurrence of double diffraction by a reflective optical system and influences of an absorber pattern and a multilayer film. However, the present disclosure is not limited thereto, and can be applied to, for example, a pattern forming thin film designed such that the phase difference φ_{M} at the center wavelength λ_{M} of EUV light is n (180 degrees). When the phase difference φ_{M} is n (180 degrees), a magnitude of the phase difference Δφ (=φ_{H}−φ_{L}) can be suppressed to 17 degrees or less by setting an absolute value of the coefficient P to 0.09 or less in a wavelength band (φ_{L} to λ_{H}) of EUV light.

Hereinafter, the embodiment of the present disclosure will be specifically described with reference to the drawings. Note that the following embodiment is one mode for embodying the present disclosure and does not limit the present disclosure within a scope thereof. Note that in the drawings, the same or corresponding parts are denoted by the same reference signs, and description thereof may be simplified or omitted.

<Configuration of Reflective Mask Blank 100 and Method for Manufacturing the Same>

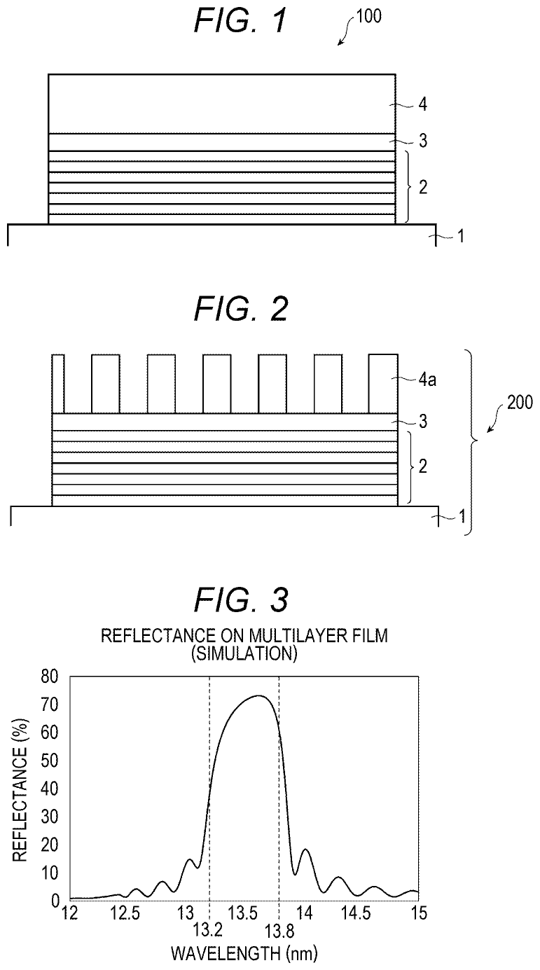

FIG. 1 is a schematic cross-sectional view of a main part for describing a configuration of a reflective mask blank 100 of the present embodiment. As illustrated in FIG. 1, the reflective mask blank 100 includes a substrate 1, a multilayer reflective film 2, a protective film 3, and an absorber film 4, and has a structure in which these are layered in this order. The multilayer reflective film 2 is formed on a side of a first main surface (front surface) and reflects EUV light that is exposure light with a high reflectance. The protective film 3 is disposed in order to protect the multilayer reflective film 2 and is formed of a material having resistance to an etchant and a cleaning liquid used when the absorber film 4 described later is patterned. The absorber film 4 absorbs EUV light and has a phase shift function. In addition, a conductive film (not illustrated) for electrostatic chuck is formed on a side of a second main surface (back surface) of the substrate 1. Note that there may be an etching mask film on the absorber film 4.

In the present specification, the expression “there is the multilayer reflective film 2 on a main surface of the substrate 1” means that the multilayer reflective film 2 is disposed in contact with a surface of the substrate 1, and also means that there is another film between the substrate 1 and the multilayer reflective film 2. The same applies to other films. For example, the expression “there is a film B on a film A” means that the film A and the film B are disposed so as to be in direct contact with each other, and also means that there is another film between the film A and the film B. In addition, in the present specification, for example, the expression “a film A is disposed in contact with a surface of a film B” means that the film A and the film B are disposed in direct contact with each other without another film interposed between the film A and the film B.

Hereinafter, the present embodiment will be described for each layer.

<<Substrate 1>>

As the substrate 1, a material having a low thermal expansion coefficient in a range of 0±5 ppb/° C. is preferably used in order to prevent distortion of an absorber pattern (transfer pattern) 4a (see FIG. 2) due to heat at the time of exposure to EUV light. As a material having a low thermal expansion coefficient in this range, for example, SiO₂—TiO₂-based glass, multicomponent-based glass ceramic, or the like can be used.

A first main surface on a side of the substrate 1 on which a transfer pattern (to which an absorber pattern 4a described later corresponds) is formed has been subjected to surface treatment so as to have a high flatness from a viewpoint of obtaining at least pattern transfer accuracy and position accuracy. In a case of EUV exposure, a flatness in an area of 132 mm×132 mm of the main surface (first main surface) on the side of the substrate 1 on which the transfer pattern is formed is preferably 0.1 μm or less, more preferably 0.05 μm or less, and particularly preferably 0.03 μm or less. In addition, a second main surface on a side opposite to the side on which the transfer pattern is formed is a surface to be electrostatically chucked at the time of setting on an exposure apparatus, and a flatness in an area of 132 mm×132 mm of the second main surface is preferably 0.1 μm or less, more preferably 0.05 μm or less, and particularly preferably 0.03 μm or less. Note that the flatness in an area of 142 mm×142 mm on a side of the second main surface in the reflective mask blank 100 is preferably 1 μm or less, more preferably 0.5 μm or less, and particularly preferably 0.3 μm or less.

In addition, a high surface smoothness of the substrate 1 is also an extremely important item. A surface roughness of the first main surface of the substrate 1 is preferably 0.1 nm or less in terms of root mean square roughness (RMS). Note that the surface smoothness can be measured with an atomic force microscope.

Furthermore, the substrate 1 preferably has a high rigidity in order to suppress deformation due to a film stress applied to a film (such as the multilayer reflective film 2) formed on the substrate 1. In particular, the substrate 1 preferably has a high Young's modulus of 65 GPa or more.

<<Multilayer Reflective Film 2>>

The multilayer reflective film 2 imparts a function of reflecting EUV light in a reflective mask 200, and is a multilayer film in which layers containing elements having different refractive indices as main components are periodically layered.

Generally, as the multilayer reflective film 2, a multilayer film is used in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. When a stack of the high refractive index layer and the low refractive index layer in which the high refractive index layer and the low refractive index layer are layered in this order from the substrate 1 side is counted as one period, the multilayer film may be formed by building up the stack for a plurality of periods. In addition, when a stack of the low refractive index layer and the high refractive index layer in which the low refractive index layer and the high refractive index layer are layered in this order from the substrate 1 side is counted as one period, the multilayer film may be formed by building up the stack for a plurality of periods. Note that a layer on an outermost surface of the multilayer reflective film 2, that is, a surface layer of the multilayer reflective film 2 on a side opposite to the substrate 1 is preferably a high refractive index layer. In the above-described multilayer film, when a stack of the high refractive index layer and the low refractive index layer in which the high refractive index layer and the low refractive index layer are layered in this order from the substrate 1 is counted as one period and the stack is built up for a plurality of periods, the uppermost layer is the low refractive index layer. In this case, when the low refractive index layer constitutes the outermost surface of the multilayer reflective film 2, the low refractive index layer is easily oxidized and a reflectance of the reflective mask 200 is reduced. Therefore, it is preferable to further form the high refractive index layer on the low refractive index layer that is the uppermost layer to form the multilayer reflective film 2. Meanwhile, in the multilayer film described above, when a stack of the low refractive index layer and the high refractive index layer in which the low refractive index layer and the high refractive index layer are layered in this order from the substrate 1 side is counted as one period and the stack is built up for a plurality of periods, the uppermost layer is the high refractive index layer, which is good as it is.

In the present embodiment, a layer containing silicon (Si) is adopted as the high refractive index layer. As a material containing Si, a Si compound containing Si and boron (B), carbon (C), nitrogen (N), and oxygen (O) can be used in addition to a Si simple substance. By using the layer containing Si as the high refractive index layer, the EUV lithography reflective mask 200 having an excellent reflectance with respect to EUV light can be obtained. In addition, in the present embodiment, a glass substrate is preferably used as the substrate 1. Si also has excellent adhesion to the glass substrate. In addition, as the low refractive index layer, a metal simple substance selected from molybdenum (Mo), ruthenium (Ru), rhodium (Rh), and platinum (Pt), or an alloy thereof is used. For example, as the multilayer reflective film 2 with respect to EUV light having a wavelength of 13 nm to 14 nm, a Mo/Si periodic layered film in which a Mo film and a Si film are alternately layered for about 40 to 60 periods is preferably used. Note that the high refractive index layer that is the uppermost layer of the multilayer reflective film 2 may be formed of silicon (Si).

A reflectance of the multilayer reflective film 2 alone is usually 65% or more, and an upper limit thereof is usually 73%. Note that the film thickness and the period of each constituent layer of the multilayer reflective film 2 only need to be appropriately selected according to an exposure wavelength and are selected so as to satisfy the Bragg reflection law. In the multilayer reflective film 2, there are a plurality of high refractive index layers and a plurality of low refractive index layers, but the film thickness does not need to be the same between the high refractive index layers and between the low refractive index layers. In addition, the film thickness of the Si layer on the outermost surface of the multilayer reflective film 2 can be adjusted in a range that does not lower the reflectance. The film thickness of the Si layer (high refractive index layer) on the outermost surface can be in a range of 3 nm to 10 nm.

A method for forming the multilayer reflective film 2 is publicly known in this technical field. The multilayer reflective film 2 can be formed by forming each layer in the multilayer reflective film 2, for example, by an ion beam sputtering method. In the case of the Mo/Si periodic layered film described above, first, a Si film having a thickness of about 4 nm is formed on the substrate 1 using a Si target, for example, by an ion beam sputtering method. Thereafter, a Mo film having a thickness of about 3 nm is formed using a Mo target. This stack of a Si film and a Mo film is counted as one period and the stack is build up for 40 to 60 periods to form the multilayer reflective film 2 (the layer on the outermost surface is a Si layer). Note that, for example, when the number of periods of the multilayer reflective film 2 is 60, the number of steps is larger than that in a case of 40 periods, but a reflectance with respect to EUV light can be increased. In addition, when the multilayer reflective film 2 is formed, the multilayer reflective film 2 is preferably formed by supplying krypton (Kr) ion particles from an ion source and performing ion beam sputtering.

<<Protective Film 3>>

The reflective mask blank 100 of the present embodiment preferably includes the protective film 3 between the multilayer reflective film 2 and the absorber film 4.

The protective film 3 can be formed on the multilayer reflective film 2 or in contact with a surface of the multilayer reflective film 2 in order to protect the multilayer reflective film 2 from dry etching and cleaning in a process of manufacturing the reflective mask 200 described later. The protective film 3 is formed of a material having resistance to an etchant and a cleaning liquid used when the absorber film 4 is patterned. The protective film 3 is formed on the multilayer reflective film 2, whereby it is possible to suppress damage to a surface of the multilayer reflective film 2 when the reflective mask 200 (EUV mask) is manufactured using the substrate 1 including the multilayer reflective film 2 and the protective film 3. Therefore, a reflectance characteristic of the multilayer reflective film 2 with respect to EUV light is favorable.

When the absorber film 4 in contact with a surface of the protective film 3 is a thin film made of a material containing ruthenium (Ru) (Ru-based material), a material selected from silicon-based materials such as silicon (Si), a material containing silicon (Si) and oxygen (O), a material containing silicon (Si) and nitrogen (N), and a material containing silicon (Si), oxygen (O), and nitrogen (N) can be used as a material of the protective film 3.

Meanwhile, when the absorber film 4 in contact with the surface of the protective film 3 is a thin film made of a tantalum-based material or a chromium-based material, the protective film 3 preferably contains ruthenium. The material of the protective film 3 may be a Ru metal simple substance or a Ru alloy containing Ru and at least one type of metal selected from titanium (Ti), niobium (Nb), molybdenum (Mo), zirconium (Zr), yttrium (Y), boron (B), lanthanum (La), cobalt (Co), rhenium (Re), and the like, and may contain nitrogen.

In EUV lithography, since there are few substances that are transparent to exposure light, it is not technically easy to apply an EUV pellicle that prevents foreign matters from adhering to a mask pattern surface. For this reason, pellicle-less operation without using a pellicle has been a mainstream. In addition, in EUV lithography, exposure contamination such as carbon film deposition on a reflective mask or an oxide film growth due to EUV exposure occurs. Therefore, at a stage where the EUV exposure reflective mask 200 is used for manufacturing a semiconductor device, it is necessary to remove foreign matters and contamination on the mask by frequently cleaning the reflective mask 200. Therefore, the EUV exposure reflective mask 200 is required to have extraordinary mask cleaning resistance as compared with an optical lithography transmissive mask. The reflective mask 200 has the protective film 3, whereby cleaning resistance to a cleaning liquid can be increased.

The film thickness of the protective film 3 is not particularly limited as long as a function of protecting the multilayer reflective film 2 is fulfilled. The film thickness of the protective film 3 is preferably 1.0 nm or more and 8.0 nm or less, and more preferably 1.5 nm or more and 6.0 nm or less from a viewpoint of a reflectance with respect to EUV light.

As a method for forming the protective film 3, it is possible to adopt a film forming method similar to a publicly known one without any particular limitation. Specific examples thereof include a sputtering method and an ion beam sputtering method.

<<Absorber Film>>

In the reflective mask blank 100 of the present embodiment, the absorber film (pattern forming thin film) 4 is formed on the multilayer reflective film 2 or the protective film 3 formed on the multilayer reflective film 2. In the absorber film 4, the absorber pattern 4a is formed in a state of the reflective mask 200, and the absorber pattern 4a constitutes a transfer pattern.

A relative reflectance R of the absorber film 4 to a reflectance of the multilayer reflective film 2 with respect to EUV exposure light (13.5 nm as a center wavelength) is preferably 1% or more, and more preferably 2% or more. The relative reflectance R is preferably 40% or less. This is for ensuring a sufficient contrast in a mask test for EUV exposure light and ensuring a sufficient contrast in a pattern image at the time of exposure transfer.

In the reflective mask 200 of the present embodiment described later, in a portion where the absorber film 4 (absorber pattern 4a) is disposed, a part of light is reflected at a level that does not adversely affect pattern transfer while EUV light is absorbed and attenuated. Meanwhile, in an opening (a portion where the absorber film 4 is not present), EUV light is reflected by the multilayer reflective film 2 (by the multilayer reflective film 2 through the protective film 3 when there is the protective film 3). Reflected light from a portion where the absorber film 4 is formed forms a desired phase difference from reflected light from the opening. The absorber film 4 is formed such that a phase difference between reflected light from the absorber film 4 and reflected light from the multilayer reflective film 2 is 130 degrees to 230 degrees with respect to light having a wavelength λ_{M} (=13.5 nm) Light beams having a reversed phase difference near 180 degrees or 220 degrees interfere with each other at a pattern edge portion, and an image contrast of a projected optical image is thereby improved. As the image contrast is improved, resolution is increased, and various exposure-related margins such as an exposure margin and a focus margin increase.

The absorber film 4 is made of a material containing a metal element. The metal element can be a metal element in a broad sense, and can be selected from an alkali metal, an alkaline earth metal, a transition metal, and a metalloid. The absorber film 4 can be selected from the above-described metal elements in a broad sense as long as the metal elements have etching selectivity with the multilayer reflective film 2 (etching selectivity with the protective film 3 when the protective film 3 is formed). For example, as the metal element contained in the absorber film 4, chromium (Cr), vanadium (V), palladium (Pd), titanium (Ti), iridium (Ir), Rh (rhodium), tantalum (Ta), niobium (Nb), molybdenum (Mo), ruthenium (Ru), tin (Sn), platinum (Pt), or the like can be used.

The absorber film 4 can contain at least one or more selected from oxygen, nitrogen, carbon, and boron without departing from the effect of the present disclosure.

When a refractive index of the absorber film 4 with respect to light having a wavelength λ_{L} of 13.2 nm is represented by n_{L}, a refractive index of the absorber film 4 with respect to light having a wavelength λ_{M} of 13.5 nm is represented by n_{M}, a refractive index of the absorber film 4 with respect to light having a wavelength λ_{H} of 13.8 nm is represented by n_{H}, and a coefficient P=[(1−n_{H})/λ_{H}−(1−n_{L})/λ_{L})]/[(1−n_{M})/λ_{M}] is satisfied, an absolute value of the coefficient P is 0.09 or less. As a result, when exposure transfer is performed with an EUV exposure apparatus, a magnitude of a phase difference Δφ (=φ_{H}−φ_{L}) in wavelength band of λ_{L} to λ_{H} of EUV light can be suppressed to 20 degrees or less.

In the absorber film 4, when an absolute value of the coefficient P is 0.085 or less in the wavelength band of λ_{L}=13.2 nm to λ_{H}=13.8 nm of EUV light, the phase difference Op can be suppressed to 18 degrees or less, which is preferable. In addition, in the absorber film 4, when the absolute value of the coefficient P is 0.07 or less in the wavelength band of λ_{L}=13.2 nm to λ_{H}=13.8 nm of EUV light, the phase difference Op can be suppressed to 15 degrees or less, which is more preferable. Furthermore, in the absorber film 4, when the absolute value of the coefficient P is 0.045 or less in the wavelength band of λ_{L}=13.2 nm to λ_{H}=13.8 nm of EUV light, the phase difference Op can be suppressed to 10 degrees or less, which is still more preferable.

When a refractive index of the absorber film 4 with respect to light having a wavelength λ_{L} of 13.0 nm is represented by n_{L}, a refractive index of the absorber film 4 with respect to light having a wavelength λ_{M} of 13.5 nm is represented by n_{M}, a refractive index of the absorber film 4 with respect to light having a wavelength λ_{H} of 14.0 nm is represented by n_{H}, and a coefficient P=[(1−n_{H})/λ_{H}−(1−n_{L})/λ_{L})]/[(1−n_{M})/λ_{M}] is satisfied, an absolute value of the coefficient P is 0.15 or less. As a result, when exposure transfer is performed with an EUV exposure apparatus, a magnitude of a phase difference Δφ (=φ_{H}−φ_{L}) in a wavelength band of λ_{L} to λ_{H} of EUV light can be suppressed to 35 degrees or less.

In the absorber film 4, when an absolute value of the coefficient P is 0.14 or less in the wavelength band of λ_{L}=13.0 nm to λ_{H}=14.0 nm of EUV light, the phase difference Δφ can be suppressed to 30 degrees or less, which is preferable. In addition, in the absorber film 4, when the absolute value of the coefficient P is 0.11 or less in the wavelength band of λ_{L}=13.0 nm to λ_{H}=14.0 nm of EUV light, the phase difference Op can be suppressed to 25 degrees or less, which is more preferable. Furthermore, in the absorber film 4, when the absolute value of the coefficient P is 0.09 or less in the wavelength band of λ_{L}=13.0 nm to λ_{H}=14.0 nm of EUV light, the phase difference Op can be suppressed to 20 degrees or less, which is still more preferable.

The material of the absorber film 4 is not particularly limited as described above, but a tantalum-based material or a chromium-based material can be preferably used. As the tantalum-based material, in addition to a tantalum metal, for example, a material containing tantalum (Ta) and one or more elements selected from nitrogen (N), oxygen (O), boron (B), and carbon (C) is preferably applied. Among these materials, a material containing tantalum (Ta) and at least one element selected from oxygen (O) and boron (B) is preferable. When the absorber film 4 is made of a material containing chromium, in addition to a chromium metal, for example, a material containing chromium (Cr) and one or more elements selected from oxygen (O), nitrogen (N), carbon (C), boron (B), and fluorine (F) is preferably applied. In particular, a material containing a nitride of chromium (Cr) is preferable.

A refractive index n_{M} of the absorber film 4 with respect to light having a wavelength λ_{M} (=13.5 nm) is preferably 0.960 or less, and more preferably 0.955 or less. The refractive index n_{M} of the absorber film 4 is preferably 0.850 or more, and more preferably 0.870 or more.

An extinction coefficient λ_{M} of the absorber film 4 with respect to light having the wavelength λ_{M} is preferably 0.10 or less, more preferably 0.08 or less, and still more preferably 0.05 or less. From results of an optical simulation, it is presumed that a light intensity of reflected light from the multilayer reflective film 2 is stronger than that of reflected light from the absorber film 4 with respect to light having a wavelength of 13.5 nm, and the reflected light from the absorber film 4 decreases as the extinction coefficient λ_{M} of the absorber film 4 increases. By setting the extinction coefficient λ_{M} in the above range, it is presumed that a decrease in reflected light from the absorber film 4 can be suppressed, which is preferable.

Depending on a pattern and an exposure condition, in order to obtain a phase shift effect, an absolute reflectance of a transfer pattern (absorber pattern 4a) with respect to EUV light (13.5 nm which is a center wavelength) is preferably 1% to 30%, and more preferably 2% to 25%.

The phase difference and the reflectance of the absorber film 4 can be adjusted by changing the refractive indices n_{L}, n_{M}, and n_{H} and the extinction coefficients k_{L}, k_{M}, and k_{H} with respect to EUV exposure light, and the film thickness d. The film thickness of the absorber film 4 is preferably less than 100 nm or less, more preferably 98 nm or less, and still more preferably 90 nm or less. The film thickness of the absorber film 4 is preferably 30 nm or more. Note that when the protective film 3 is included, the phase difference and the reflectance of the absorber film 4 can also be adjusted in consideration of the refractive index n, the extinction coefficient k, and the film thickness of the protective film 3.

The absorber film 4 containing the predetermined material described above can be formed by known methods such as a sputtering method such as a DC sputtering method or an RF sputtering method, and a reactive sputtering method using an oxygen gas or the like. A target may contain one type of metal, and when the absorber film 4 is made of two or more types of metals, an alloy target containing two or more types of metals (for example, Ru and Cr) can be used. When the absorber film 4 is made of two or more types of metals, a thin film constituting the absorber film 4 can be formed by, for example, co-sputtering using a Ru target and a Cr target.

Note that the absorber film 4 may be a multilayer film including two or more layers. In this case, all the layers of the absorber film 4 preferably satisfy a condition that an absolute value of the coefficient P is 0.09 or less.

<<Etching Mask Film>>

An etching mask film (not illustrated) can be formed on the absorber film 4 or in contact with a surface of the absorber film 4. As a material of the etching mask film, a material with which an etching selective ratio of the absorber film 4 to the etching mask film is high is used. Here, the expression “etching selective ratio of B to A” means a ratio between an etching rate of A which is a layer that does not need to be etched (a layer serving as a mask) and an etching rate of B which is a layer that needs to be etched. Specifically, “etching selective ratio of B to A” is specified by a formula of “etching selective ratio of B to A=etching rate of B/etching rate of A”. In addition, “high selective ratio” means that a value of the selective ratio defined above is large as compared with that of a comparison target. The etching selective ratio of the absorber film 4 to the etching mask film is preferably 1.5 or more, and more preferably 3 or more.

The film thickness of the etching mask film is desirably 2 nm or more from a viewpoint of obtaining a function as an etching mask that accurately forms a transfer pattern on the absorber film 4. In addition, the film thickness of the etching mask film is desirably 15 nm or less from a viewpoint of reducing the film thickness of a resist film.

<<Conductive Film>>

A conductive film (not illustrated) for electrostatic chuck is generally formed on the second main surface (back surface) side of the substrate 1 (side opposite to the multilayer reflective film 2 forming surface). An electrical characteristic (sheet resistance) required for the conductive film for electrostatic chuck is usually 100Ω/□ (Ω/square) or less. The conductive film can be formed, for example, by a magnetron sputtering method or an ion beam sputtering method using a target of a metal such as chromium (Cr) or tantalum (Ta) or an alloy thereof.

A material containing chromium (Cr) for the conductive film is preferably a Cr compound containing Cr and further containing at least one selected from boron (B), nitrogen (N), oxygen (O), and carbon (C).

As a material containing tantalum (Ta) for the conductive film, it is preferable to use Ta (tantalum), an alloy containing Ta, or a Ta compound containing either Ta or an alloy containing Ta and at least one selected from boron, nitrogen, oxygen, and carbon.

The thickness of the conductive film is not particularly limited as long as a function as being for electrostatic chuck is fulfilled. The thickness of the conductive film is usually 10 nm to 200 nm. In addition, the conductive film further adjusts a stress on the second main surface side of the mask blank 100. That is, the conductive film is adjusted such that the flat reflective mask blank 100 can be obtained in balance with a stress from various films formed on the first main surface side.

<Reflective Mask 200 and Method for Manufacturing the Same>

In the reflective mask 200 of the present embodiment, a transfer pattern (absorber pattern 4a) is formed on the absorber film 4 of the reflective mask blank 100. The absorber film 4 (absorber pattern 4a) on which the transfer pattern is formed is similar to the absorber film 4 of the reflective mask blank 100 of the present embodiment described above. By patterning the absorber film 4 of the reflective mask blank 100 of the present embodiment described above, the transfer pattern (absorber pattern 4a) can be formed. Patterning of the absorber film 4 can be performed with a predetermined dry etching gas. The absorber pattern 4a of the reflective mask 200 can absorb EUV light and reflect a part of the EUV light at a predetermined phase difference from an opening (a portion where the absorber pattern 4a is not formed). As the predetermined dry etching gas, a mixed gas of a chlorine-based gas and an oxygen gas, an oxygen gas, a fluorine-based gas, or the like can be used. In order to pattern the absorber pattern 4a, an etching mask film can be disposed on the absorber pattern 4a as necessary. In this case, the absorber film 4 can be dry-etched using an etching mask pattern as a mask to form the absorber pattern 4a.

A method for manufacturing the reflective mask 200 using the reflective mask blank 100 of the present embodiment will be described.

The reflective mask blank 100 is prepared, and a resist film is formed on the absorber film 4 on the first main surface of the reflective mask blank 100 (this is not necessary when the resist film is included in the reflective mask blank 100). A desired transfer pattern is drawn (exposed) on this resist film and further developed and rinsed, whereby a predetermined resist pattern (resist film having a transfer pattern) is formed.

Next, using this resist pattern as a mask, the absorber film 4 is etched to form the absorber pattern 4a (absorber film 4 having a transfer pattern). After the absorber pattern 4a is formed, the remaining resist pattern is removed (When an etching mask film is formed, the etching mask film is etched using the resist pattern as a mask to form an etching mask pattern, and the absorber pattern 4a is formed using this etching mask pattern as a mask to remove the etching mask pattern.).

Finally, by performing wet cleaning using an acidic or alkaline aqueous solution, the reflective mask 200 of the present embodiment is manufactured.

[Method for Manufacturing Semiconductor Device]

The present embodiment is a method for manufacturing a semiconductor device, the method including a step of performing exposure transfer of a transfer pattern to a resist film on a semiconductor substrate using the reflective mask 200 described above or the reflective mask 200 manufactured by the method for manufacturing the reflective mask 200 described above. A semiconductor device can be manufactured by setting the reflective mask 200 of the present embodiment in an exposure apparatus having an EUV light exposure light source and transferring a transfer pattern to a resist film formed on a transferred substrate. Therefore, a semiconductor device having a fine and highly accurate transfer pattern can be manufactured.

[Examples and Comparative Examples]

Examples 1 to 16 and Comparative Examples 1 and 2

Hereinafter, Examples 1 to 16 and Comparative Examples 1 and 2 will be described with reference to the drawings. The present embodiment is not limited to these Examples. Note that in Examples, the same reference signs will be used for similar constituent elements, and description thereof will be simplified or omitted.

A method for manufacturing the reflective mask blank 100 will be described as Examples 1 to 16 and Comparative Examples 1 and 2.

A SiO₂—TiO₂-based glass substrate that is a low thermal expansion glass substrate having 6025 size (approximately 152 mm×152 mm×6.35 mm) and having polished both main surfaces that are a first main surface and a second main surface was prepared as the substrate 1. The main surfaces were subjected to polishing including a rough polishing step, a precision polishing step, a local processing step, and a touch polishing step such that the main surfaces were flat and smooth.

Next, a conductive film formed of a CrN film was formed on the second main surface (back surface) of the SiO₂—TiO₂-based glass substrate 1 by a magnetron sputtering (reactive sputtering) method under the following conditions. The conductive film was formed so as to have a film thickness of 20 nm in a mixed gas atmosphere of an argon (Ar) gas and a nitrogen (N₂) gas using a Cr target.

Next, the multilayer reflective film 2 was formed on the main surface (first main surface) of the substrate 1 on a side opposite to the side on which the conductive film was formed. The multilayer reflective film 2 formed on the substrate 1 was a periodic layered reflective film containing Mo and Si in order to make the multilayer reflective film 2 suitable for EUV light having a wavelength of 13.5 nm. The multilayer reflective film 2 was formed using a Mo target and a Si target by alternately building up a Mo layer and a Si layer on the substrate 1 by an ion beam sputtering method in a krypton (Kr) gas atmosphere. First, a Si film was formed so as to have a film thickness of 4.2 nm, and then a Mo film was formed so as to have a film thickness of 2.8 nm. This stack was counted as one period, the stack of a Si film and a Mo film was built up for 40 periods in a similar manner, and finally, a Si film was formed so as to have a film thickness of 4.0 nm to form the multilayer reflective film 2.

Subsequently, the protective film 3 was formed so as to have a film thickness of 3.5 nm on a surface of the multilayer reflective film 2 in an Ar gas atmosphere by a sputtering method. Note that, in Examples 1 to 16 and Comparative Examples 1 and 2 described above, as a material of the protective film 3, a material having etching resistance to a dry etching gas used for patterning the absorber film 4 was appropriately selected.

Subsequently, the absorber film 4 was formed on a surface of the protective film 3 by a sputtering method in an Ar gas atmosphere. In Examples 1 to 16 and Comparative Examples 1 and 2 described above, constituent elements of the absorber film 4 are presented in Tables 1-1 and 1-2 below, and a sputtering target suitable for each of the constituent elements was appropriately selected. Note that the absorber film 4 in Examples 1 to 16 and Comparative Examples 1 and 2 was designed such that a phase difference φ_{M} at a center wavelength λ_{M} of EUV light was 1.2π (216 degrees).

Thereafter, a predetermined cleaning treatment or the like was performed to manufacture the reflective mask blank 100 in Examples 1 to 16 and Comparative Examples 1 and 2.

Next, for the reflective mask blank 100 in Examples 1 to 16 and Comparative Examples 1 and 2, as described in the method for manufacturing the reflective mask 200 described above, a resist pattern was formed, the absorber film 4 was etched using the resist pattern as a mask to form the absorber pattern 4a (absorber film 4 having a transfer pattern), and wet cleaning using an acidic or alkaline aqueous solution was performed, thereby manufacturing the reflective mask 200 in Examples 1 to 16 and Comparative Examples 1 and 2.

Tables 1-1 and 1-2 present constituent elements of the absorber film 4, a refractive index n_{M} and an extinction coefficient λ_{M} at a center wavelength λ_{M} (=13.5 nm) of EUV light, a coefficient A_{L}=4π×(1−n_{L})/λ_{L}, a coefficient A_{M}=4π×(1−n_{M})/λ_{M}, and a coefficient A_{H}=4π×(1−n_{H})/λ_{H} at wavelengths λ_{L}=13.2 nm, λ_{M}=13.5 nm, and λ_{H}=13.8 nm, respectively, a film thickness d, and a coefficient P=(A_{H}−A_{L})/A_{M}(=[(1−n_{H})/λ_{H}−(1−n_{L})/λ_{L})]/[(1−n_{M})/λ_{M}]) and a phase difference Δφ in a wavelength band of λ_{L}=13.2 nm to λ_{H}=13.8 nm of EUV light in the reflective mask blank 100 and the reflective mask 200 in Examples 1 to 16 and Comparative Examples 1 and 2.

TABLE 1-1

| | Example 1 | Example 2 | Example 3 | Example 4 | Example 5 | Example 6 | Example 7 | Example 8 | Example 9 |
|---|---|---|---|---|---|---|---|---|---|
| Constituent element | Cr₈₀O₁₀N₁₀ | Cr₈₅N₁₅ | V | Pd | Ti | Ir₇₀Ta₁₅O₁₅ | Rh | Ta₇₀B₁₅N₁₅ | Nb |
| n_{M} (λ_{M} = 13.5 nm) | 0.9449 | 0.9361 | 0.9432 | 0.8761 | 0.9519 | 0.9374 | 0.8750 | 0.9580 | 0.9337 |
| k_{M} (λ_{M} = 13.5 nm) | 0.0304 | 0.0352 | 0.0251 | 0.0464 | 0.0142 | 0.0313 | 0.0312 | 0.0296 | 0.0617 |
| A_{L} (λ_{L} = 13.2 nm) [nm⁻¹] | 0.0504 | 0.0584 | 0.0518 | 0.1125 | 0.0437 | 0.0564 | 0.1119 | 0.0377 | 0.0594 |
| A_{M} (λ_{M} = 13.5 nm) [nm⁻¹] | 0.0513 | 0.0595 | 0.0529 | 0.1153 | 0.0448 | 0.0583 | 0.1163 | 0.0391 | 0.0617 |
| A_{H} (λ_{H} = 13.8 nm) [nm⁻¹] | 0.0521 | 0.0605 | 0.0541 | 0.1181 | 0.0459 | 0.0602 | 0.1207 | 0.0406 | 0.0641 |
| Film thickness d (1.2 | 73.51 | 63.40 | 71.27 | 32.69 | 84.22 | 64.67 | 32.40 | 96.41 | 61.12 |
| π@13.5 nm) | | | | | | | | | |
| P [λ = 13.2-13.8 nm] | 0.0337 | 0.0341 | 0.0428 | 0.0486 | 0.0505 | 0.0648 | 0.0754 | 0.0753 | 0.0761 |
| Phase difference Δϕ | 7.27 | 7.36 | 9.24 | 10.50 | 10.91 | 14.00 | 16.29 | 16.27 | 16.44 |
| [deg] [λ = 13.2-13.8 | | | | | | | | | |
| nm] | | | | | | | | | |
| A_{L} (λ_{L} = 13.0 nm) [nm⁻¹] | 0.0498 | 0.0577 | 0.0511 | 0.1104 | 0.0429 | 0.0553 | 0.1089 | 0.0368 | 0.0578 |
| A_{H} (λ_{H} = 14.0 nm) [nm⁻¹] | 0.0527 | 0.0611 | 0.0549 | 0.1198 | 0.0467 | 0.0614 | 0.1234 | 0.0416 | 0.0656 |
| P [λ = 13.0-14.0 nm] | 0.0560 | 0.0566 | 0.0712 | 0.0807 | 0.0837 | 0.1051 | 0.1245 | 0.1245 | 0.1265 |
| Phase difference Δϕ | 12.11 | 12.25 | 15.40 | 17.46 | 18.10 | 22.73 | 26.92 | 26.94 | 27.36 |
| [deg] [λ = 13.0-14.0 | | | | | | | | | |
| nm] | | | | | | | | | |

TABLE 1-2

| | Example | Example | Example | Example | Example | Example | Example | Comparative | Comparative |
|---|---|---|---|---|---|---|---|---|---|
| | 10 | 11 | 12 | 13 | 14 | 15 | 16 | Example 1 | Example 2 |
| Constituent element | Mo | Ru₈₀Cr₁₀N₁₀ | Ru₇₀Rh₃₀ | Ru₈₀Nb₂₀ | Ru₉₅N₅ | Ru | SnO | W | SiO₂ |
| n_{M} (λ_{M} = 13.5 nm) | 0.9238 | 0.8974 | 0.8830 | 0.8965 | 0.8938 | 0.8863 | 0.9399 | 0.9328 | 0.9780 |
| k_{M} (λ_{M} = 13.5 nm) | 0.0064 | 0.0185 | 0.0214 | 0.0143 | 0.0162 | 0.0171 | 0.0635 | 0.0330 | 0.0108 |
| A_{L} (λ_{L} = 13.2 nm) [nm⁻¹] | 0.0682 | 0.0916 | 0.1044 | 0.0923 | 0.0946 | 0.1012 | 0.0571 | 0.0594 | 0.0194 |
| A_{M} (λ_{M} = 13.5 nm) [nm⁻¹] | 0.0710 | 0.0955 | 0.1089 | 0.0964 | 0.0988 | 0.1058 | 0.0559 | 0.0625 | 0.0205 |
| A_{H} (λ_{H} = 13.8 nm) [nm⁻¹] | 0.0739 | 0.0995 | 0.1135 | 0.1005 | 0.1032 | 0.1105 | 0.0544 | 0.0659 | 0.0214 |
| Film thickness d (1.2 | 53.13 | 39.46 | 34.61 | 39.13 | 38.15 | 35.63 | 67.45 | 60.32 | 184.31 |
| π@13.5 nm) | | | | | | | | | |
| P [λ = 13.2-13.8 nm] | 0.0807 | 0.0827 | 0.0835 | 0.0856 | 0.0867 | 0.0874 | −0.0481 | 0.1041 | 0.0985 |
| Phase difference Δϕ | 17.43 | 17.86 | 18.05 | 18.49 | 18.74 | 18.89 | −10.38 | 22.49 | 21.28 |
| [deg] [λ = 13.2-13.8 | | | | | | | | | |
| nm] | | | | | | | | | |
| A_{L} (λ_{L} = 13.0 nm) [nm⁻¹] | 0.0663 | 0.0890 | 0.1014 | 0.0896 | 0.0918 | 0.0982 | 0.0578 | 0.0576 | 0.0185 |
| A_{H} (λ_{H} = 14.0 nm) [nm⁻¹] | 0.0758 | 0.1020 | 0.1163 | 0.1031 | 0.1058 | 0.1134 | 0.0532 | 0.0679 | 0.0219 |
| P [λ = 13.0-14.0 nm] | 0.1334 | 0.1358 | 0.1373 | 0.1408 | 0.1424 | 0.1435 | −0.0823 | 0.1651 | 0.1675 |
| Phase difference Δϕ | 28.86 | 29.37 | 29.71 | 30.45 | 30.80 | 31.05 | −17.80 | 35.71 | 36.22 |
| [deg] [λ = 13.0-14.0 | | | | | | | | | |
| nm] | | | | | | | | | |

As presented in Tables 1-1 and 1-2, in each of the absorber films 4 indicated in Examples 1 to 16, the film thickness is less than 100 nm, in a wavelength band of λ_{L}=13.2 nm to λ_{H}=13.8 nm of EUV light, an absolute value of the coefficient P is 0.09 or less, and the phase difference Δφ can be suppressed to 20 degrees or less. In each of the absorber films 4 indicated in Examples 1 to 11 and 16, furthermore, in the wavelength band of λ_{L}=13.2 nm to λ_{H}=13.8 nm of EUV light, an absolute value of the coefficient P is 0.085 or less, and the phase difference Δφ can be suppressed to 18 degrees or less. In addition, in each of the absorber films 4 indicated in Examples 1 to 6 and 16, in the wavelength band of λ_{L}=13.2 nm to λ_{H}=13.8 nm of EUV light, an absolute value of the coefficient P is 0.07 or less, and the phase difference Δφ can be suppressed to 15 degrees or less. Furthermore, in each of the absorber films 4 indicated in Examples 1 to 3, in the wavelength band of λ_{L}=13.2 nm to λ_{H}=13.8 nm of EUV light, an absolute value of the coefficient P is 0.045 or less, and the phase difference Δφ can be suppressed to 10 degrees or less.

Meanwhile, in Comparative Example 1, in the wavelength band of λ_{L}=13.2 nm to λ_{H}=13.8 nm of EUV light, the phase difference Op of the absorber film 4 is 22.49, which exceeds 20 degrees, and the phase difference Δφ is non-negligible. In Comparative Example 2, the film thickness of the absorber film 4 is 183.31 nm, which significantly exceeds a value less than 100 nm.

Tables 1-1 and 1-2 also present a coefficient λ_{L}=4π×(1−n_{L})/λ_{L}, a coefficient λ_{H}=4π×(1−n_{H})/λ_{H}, a coefficient P=(A_{H}−A_{L})/A_{M}, and a phase difference Op in a wavelength band of λ_{L}=13.0 nm to λ_{H}=14.0 nm of EUV light in Examples 1 to 16 and Comparative Examples 1 and 2. As presented in Tables 1-1 and 1-2, in each of the absorber films 4 indicated in Examples 1 to 16, in the wavelength band of λ_{L}=13.0 nm to λ_{H}=14.0 nm of EUV light, an absolute value of the coefficient P is 0.15 or less, and the phase difference Op can be suppressed to 35 degrees or less. In addition, in each of the absorber films 4 indicated in Examples 1 to 12 and 16, in the wavelength band of λ_{L}=13.0 nm to λ_{H}=14.0 nm of EUV light, an absolute value of the coefficient P is 0.14 or less, and the phase difference Δφ can be suppressed to 30 degrees or less. Furthermore, in each of the absorber films 4 indicated in Examples 1 to 6 and 16, in the wavelength band of λ_{L}=13.0 nm to λ_{H}=14.0 nm of EUV light, an absolute value of the coefficient P is 0.11 or less, and the phase difference Δφ can be suppressed to 25 degrees or less. Furthermore, in each of the absorber films 4 indicated in Examples 1 to 5 and 16, in the wavelength band of λ_{L}=13.0 nm to λ_{H}=14.0 nm of EUV light, an absolute value of the coefficient P is 0.09 or less, and the phase difference Δφ can be suppressed to 20 degrees or less.

In addition, Tables 2-1 and 2-2 present constituent elements of the absorber film 4, a coefficient E_{L}=4π×(1−k_{L})/λ_{L}, a coefficient E_{M}=4π×(1−k_{M})/λ_{M}, and a coefficient E_{H}=4π×(1−k_{H})/λ_{H} at wavelengths λ_{L}=13.2 nm, λ_{M}=13.5 nm, and λ_{H}=13.8 nm, respectively, and a coefficient F=(E_{H}−E_{L})/E_{M}(=[(1−k_{H})/λ_{H}−(1−k_{L})/λ_{L})]/[(1−k_{M})/λ_{M}]) in a wavelength band of λ_{L}=13.2 nm to λ_{H}=13.8 nm of EUV light in the reflective mask blank 100 and the reflective mask 200 in Examples 1 to 16 and Comparative Examples 1 and 2 (k_{L}, k_{M}, and k_{H} represent extinction coefficients at wavelengths λ_{L}=13.2 nm, λ_{M}=13.5 nm, and λ_{H}=13.8 nm, respectively). Note that Tables 2-1 and 2-2 also present a coefficient E_{L}=4π×(1−k_{L})/λ_{L}, a coefficient E_{M}=4π×(1−λ_{M})/λ_{M}, and a coefficient E_{H}=4π×(1−k_{H})/λ_{H} in a wavelength band of λ_{L}=13.0 nm to λ_{H}=14.0 nm of EUV light, and a coefficients F=(E_{H}−E_{L})/E_{M}(−[(1−k_{H})/λ_{H}−(1−k_{L})/λ_{L})−λ_{M})/λ_{M}]) in the wavelength band of λ_{L}=13.0 nm to λ_{H}=14.0 nm of EUV light in Examples 1 to 16 and Comparative Examples 1 and 2.

TABLE 2-1

| | Example 1 | Example 2 | Example 3 | Example 4 | Example 5 | Example 6 | Example 7 | Example 8 | Example 9 |
|---|---|---|---|---|---|---|---|---|---|
| Constituent element | Cr₈₀O₁₀N₁₀ | Cr₈₅N₁₅ | V | Pd | Ti | Ir₇₀Ta₁₅O₁₅ | Rh | Ta₇₀B₁₅N₁₅ | Nb |
| E_{L} (λ_{L} = 13.2 nm) | 0.0274 | 0.0318 | 0.0230 | 0.0384 | 0.0130 | 0.0280 | 0.0253 | 0.0275 | 0.0565 |
| E_{M} (λ_{M} = 13.5 nm) | 0.0283 | 0.0328 | 0.0234 | 0.0432 | 0.0132 | 0.0291 | 0.0290 | 0.0276 | 0.0574 |
| E_{H} (λ_{H} = 13.8 nm) | 0.0292 | 0.0338 | 0.0238 | 0.0485 | 0.0134 | 0.0306 | 0.0334 | 0.0277 | 0.0583 |
| F [λ = 13.2-13.8 nm] | 0.0640 | 0.0636 | 0.0348 | 0.2331 | 0.0306 | 0.0887 | 0.2783 | 0.0062 | 0.0314 |
| E_{L} (λ_{L} = 13.0 nm) | 0.0268 | 0.0311 | 0.0227 | 0.0352 | 0.0128 | 0.0272 | 0.0231 | 0.0274 | 0.0559 |
| E_{H} (λ_{H} = 14.0 nm) | 0.0298 | 0.0345 | 0.0240 | 0.0521 | 0.0134 | 0.0316 | 0.0364 | 0.0278 | 0.0589 |
| F [λ = 13.0-14.0 nm] | 0.1057 | 0.1050 | 0.0577 | 0.3907 | 0.0453 | 0.1481 | 0.4580 | 0.0129 | 0.0525 |

TABLE 2-2

| | Example | Example | Example | Example | Example | Example | Example | Comparative | Comparative |
|---|---|---|---|---|---|---|---|---|---|
| | 10 | 11 | 12 | 13 | 14 | 15 | 16 | Example 1 | Example 2 |
| Constituent element | Mo | Ru₈₀Cr₁₀N₁₀ | Ru₇₀Rh₃₀ | Ru₈₀Nb₂₀ | Ru₉₅N₅ | Ru | SnO | W | SiO₂ |
| E_{L} (λ_{L} = 13.2 nm) | 0.0056 | 0.0152 | 0.0172 | 0.0115 | 0.0129 | 0.0136 | 0.0566 | 0.0307 | 0.0097 |
| E_{M} (λ_{M} = 13.5 nm) | 0.0060 | 0.0172 | 0.0199 | 0.0134 | 0.0151 | 0.0159 | 0.0591 | 0.0307 | 0.0100 |
| E_{H} (λ_{H} = 13.8 nm) | 0.0065 | 0.0197 | 0.0231 | 0.0156 | 0.0177 | 0.0187 | 0.0616 | 0.0314 | 0.0104 |
| F [λ = 13.2-13.8 nm] | 0.1455 | 0.2588 | 0.3016 | 0.3045 | 0.3136 | 0.3201 | 0.0846 | 0.0218 | 0.0706 |
| E_{L} (λ_{L} = 13.0 nm) | 0.0054 | 0.0141 | 0.0156 | 0.0105 | 0.0118 | 0.0124 | 0.0550 | 0.0308 | 0.0095 |
| E_{H} (λ_{H} = 14.0 nm) | 0.0068 | 0.0215 | 0.0255 | 0.0172 | 0.0196 | 0.0208 | 0.0630 | 0.0319 | 0.0106 |
| F [λ = 13.0-14.0 nm] | 0.2405 | 0.4278 | 0.4976 | 0.5028 | 0.5184 | 0.5291 | 0.1351 | 0.0375 | 0.1170 |

Regarding the extinction coefficient k, no significant difference was found among Examples 1 to 16 and Comparative Examples 1 and 2.

The reflective mask 200 obtained in Examples 1 to 16 was set in an EUV scanner, EUV exposure was performed on a wafer having a film to be processed and a resist film formed on a semiconductor substrate, and the exposed resist film was developed to form a resist pattern on the semiconductor substrate with the film to be processed.

The reflective mask 200 obtained in Examples 1 to 16 includes the absorber pattern 4a in which the phase difference φ_{M} at the center wavelength λ_{M} of EUV light is 1.2 n, and an absolute value of the coefficient P is 0.09 or less in the wavelength band of λ_{L}=13.2 nm to λ_{H}=13.8 nm of EUV light. As a result, when EUV light was used as exposure light, a phase difference Op could be suppressed to 20 degrees or less in the wavelength band of λ_{L}=13.2 nm to λ_{H}=13.8 nm of EUV light, a required fine pattern could be accurately formed, and a semiconductor device having a fine and highly accurate transfer pattern could be manufactured.

Furthermore, this resist pattern was transferred to a film to be processed by etching, and through various steps such as formation of an insulating film and a conductive film, introduction of a dopant, and annealing, a semiconductor device having desired characteristics could be manufactured at a high yield.

The reflective mask 200 of Comparative Example 1 includes the absorber pattern 4a in which an absolute value of the coefficient P exceeds 0.09 in the wavelength band of λ_{L}=13.2 nm to λ_{H}=13.8 nm of EUV light. As a result, when EUV light was used as exposure light, a phase difference Δφ was 22.49 degrees, which could not be suppressed to 20 degrees or less, in the wavelength band of λ_{L}=13.2 nm to λ_{H}=13.8 nm of EUV light, and a phase shift effect could not be sufficiently obtained. Therefore, a required fine pattern could not be accurately formed, and a semiconductor device having a fine and highly accurate transfer pattern could not be manufactured.

Furthermore, this resist pattern was transferred to a film to be processed by etching, and through various steps such as formation of an insulating film and a conductive film, introduction of a dopant, and annealing, a semiconductor device having desired characteristics could not be manufactured at a high yield.

In the reflective mask 200 of Comparative Example 2, the absorber film 4 is made of SiO₂ and does not contain a metal element. As a result, the film thickness of the absorber film 4 was 184.31 nm, which significantly exceeded 100 nm, favorable transfer characteristics cannot be obtained, and a semiconductor device having a fine and highly accurate transfer pattern cannot be manufactured.

Furthermore, this resist pattern was transferred to a film to be processed by etching, and through various steps such as formation of an insulating film and a conductive film, introduction of a dopant, and annealing, a semiconductor device having desired characteristics could not be manufactured at a high yield.

### REFERENCE SIGNS LIST

1 Substrate
2 Multilayer reflective film
3 Protective film
4 Absorber film (pattern forming thin film)
4a Absorber pattern (transfer pattern)
100 Reflective mask blank
200 Reflective mask

1. A mask blank comprising: a substrate; a multilayer reflective film above the substrate; and a pattern forming thin film above the multilayer reflective film, wherein
the thin film contains a metal,
a refractive index of the thin film with respect to light having a wavelength λ_{L} of 13.2 nm is represented by n_{L},
a refractive index of the thin film with respect to light having a wavelength λ_{M} of 13.5 nm is represented by n_{M},
a refractive index of the thin film with respect to light having a wavelength λ_{H} of 13.8 nm is represented by n_{H},
a coefficient P=[(1−n_{H})/λ_{H}−(1−n_{L})/λ_{L})]/[(1−n_{M})/λ_{M}], and
an absolute value of the coefficient P is 0.09 or less.

2. The mask blank according to claim 1, wherein the refractive index n_{M} of the thin film with respect to light having the wavelength λ_{M} is 0.96 or less.

3. The mask blank according to claim 1, wherein the thin film has a thickness of less than 100 nm.

4. The mask blank according to claim 1, further comprising a protective film between the multilayer reflective film and the thin film.

5. The mask blank according to claim 1, wherein the thin film has a phase difference of 130 degrees to 230 degrees between reflected light from the thin film and reflected light from the multilayer reflective film with respect to light having the wavelength λ_{M}.

6. A reflective mask comprising: a substrate; a multilayer reflective film above the substrate; and a thin film having a transfer pattern above the multilayer reflective film, wherein
the thin film contains a metal,
a refractive index of the thin film with respect to light having a wavelength λ_{L} of 13.2 nm is represented by n_{L},
a refractive index of the thin film with respect to light having a wavelength λ_{M} of 13.5 nm is represented by n_{M},
a refractive index of the thin film with respect to light having a wavelength λ_{H} of 13.8 nm is represented by n_{H},
a coefficient P=[(1−n_{H})/λ_{H}−(1−n_{L})/λ_{L})]/[(1−n_{M})/λ_{M}], and
an absolute value of the coefficient P is 0.09 or less.

7. The reflective mask according to claim 6, wherein the refractive index n_{M} of the thin film with respect to light having the wavelength λ_{M} is 0.96 or less.

8. The reflective mask according to claim 6, wherein the thin film has a thickness of less than 100 nm.

9. The reflective mask according to claim 6, further comprising a protective film between the multilayer reflective film and the thin film.

10. The reflective mask according to claim 6, wherein the thin film has a phase difference of 130 degrees to 230 degrees between reflected light from the thin film and reflected light from the multilayer reflective film with respect to light having the wavelength λ_{M}.

11. (canceled)

12. The mask blank according to claim 1, wherein the metal contains at least one or more selected from chromium (Cr), vanadium (V), palladium (Pd), titanium (Ti), iridium (Ir), Rh (rhodium), tantalum (Ta), niobium (Nb), molybdenum (Mo), ruthenium (Ru), tin (Sn), and platinum (Pt).

13. The mask blank according to claim 12, wherein the thin film further contains at least one or more selected from oxygen, nitrogen, carbon, and boron.

14. A mask blank comprising: a substrate; a multilayer reflective film above the substrate; and a pattern forming thin film above the multilayer reflective film, wherein
the thin film contains a metal,
a refractive index of the thin film with respect to light having a wavelength λ_{L} of 13.0 nm is represented by n_{L},
a refractive index of the thin film with respect to light having a wavelength λ_{M} of 13.5 nm is represented by n_{M},
a refractive index of the thin film with respect to light having a wavelength λ_{H} of 14.0 nm is represented by n_{H},
a coefficient P=[(1−n_{H})/λ_{H}−(1−n_{L})/λ_{L})]/[(1−n_{M})/λ_{M}], and
an absolute value of the coefficient P is 0.14 or less.

15. The mask blank according to claim 14, wherein the refractive index n_{M} of the thin film with respect to light having the wavelength λ_{M} is 0.96 or less.

16. The mask blank according to claim 14, wherein the thin film has a thickness of less than 100 nm.

17. The mask blank according to claim 14, further comprising a protective film between the multilayer reflective film and the thin film.

18. The mask blank according to claim 14, wherein the thin film has a phase difference of 130 degrees to 230 degrees between reflected light from the thin film and reflected light from the multilayer reflective film with respect to light having the wavelength λ_{M}.

19. The mask blank according to claim 14, wherein the metal contains at least one or more selected from chromium (Cr), vanadium (V), palladium (Pd), titanium (Ti), iridium (Ir), Rh (rhodium), tantalum (Ta), niobium (Nb), molybdenum (Mo), ruthenium (Ru), tin (Sn), and platinum (Pt).

20. The mask blank according to claim 19, wherein the thin film further contains at least one or more selected from oxygen, nitrogen, carbon, and boron.
